(19) United States
(12) Patent Application Publication
(10) Pub. No.: US 2019/0237699 A1
(43) Pub. Date: Aug. 1, 2019

(54) FLEXIBLE DISPLAY DEVICE

(71) Applicants: Kunshan New Flat Panel Display Technology Center Co., Ltd., Kunshan (CN); Yungu (Gu'an) Technology Co., Ltd., Langfang (CN)

(72) Inventors: Kun HU, Kunshan (CN); Jiawei LI, Kunshan (CN); Wangfeng XI, Kunshan (CN); Mengzhen LI, Kunshan (CN); Fengzhi YU, Kunshan (CN); Yucheng LIU, Kunshan (CN); Xiaokang ZHOU, Kunshan (CN); Hui PANG, Kunshan (CN); Feng YU, Kunshan (CN)

(73) Assignee: Yungu (Gu'an) Technology Co., Ltd., Langfang (CN)

(21) Appl. No.: 16/376,899

(22) Filed: Apr. 5, 2019

Related U.S. Application Data
(63) Continuation of application No. PCT/CN2018/091301, filed on Jun. 14, 2018.

(30) Foreign Application Priority Data
Aug. 31, 2017 (CN) 201710773085.0
Aug. 31, 2017 (CN) 201721112576.2

(51) Int. Cl. H01L 51/52; H01L 51/00; H01L 27/32; H01L 51/56

(52) U.S. Cl. CPC H01L 51/5253; H01L 51/56; H01L 27/3276; H01L 51/0097

(57) ABSTRACT

The flexible display device provided in the present disclosure includes: an organic light emitting structure; an organic layer covering the organic light emitting structure and filled with an inorganic material.

### CROSS-REFERENCE TO RELATED APPLICATIONS

This application is a continuation of International Application No. PCT/CN2018/091301, filed on Jun. 14, 2018, which claims priority to Chinese Patent Application No. 201710773085.0, filed on Aug. 31, 2017, and Chinese Patent Application No. 201721112576.2, filed on Aug. 31, 2017. All of the aforementioned patent applications are hereby incorporated by reference in their entireties.

### TECHNICAL FIELD

The present disclosure relates to the field of display technology, and in particular to a flexible display device.

### BACKGROUND

Flexible display devices realize display by means of Organic Light Emitting Diodes (OLEDs) provided on substrates. Because of their advantages such as simple preparation process, high luminous efficiency, high contrast, ultra-thin and ultra-light, low power consumption and easy formation of flexible structure, OLEDs have attracted wide attention in recent years. However, the organic light-emitting structures in OLED devices are very sensitive to oxygen and water vapor, and even a small amount of oxygen and water vapor permeating into the interior of the devices will deteriorate the luminous property of the devices, and will lead to a decrease in the stability of the organic material and even to an electrochemical corrosion, which seriously affects the life of the devices. Therefore, in actual use, the devices need to be packaged to isolate the device from oxygen and water vapor so as to extend the service life of the OLEDs.

As a kind of packaging methods commonly used in OLED devices packaging, thin film packaging can meet the requirements of lighter and thinner OLED devices, so many researchers turn their attention to thin film packaging. In thin film packaging, in order to limit or prevent the invasion of oxygen and water vapor, a combination of an inorganic layer and an organic layer is usually employed. The soft organic layer is used to cover the surface steps of the OLED and impurities, and the hard inorganic layer is used to block the invasion of oxygen and water vapor. However, due to the low fracture strain of the inorganic layer, the planar structure design thereof is easy to generate large strain and thus fracture when the device is bent, which leads to a decrease in barrier performance and increases the risk of package failure.

### SUMMARY

According to the above, the present disclosure is devoted to providing a flexible display device to solve the problem that the flexible display device of the prior art is easily broken during the bending process due to the planar structure of the inorganic barrier layer, thereby resulting in low performance of barrier from oxygen and water vapor and high risk of package failure.

The present disclosure provides a flexible display device including: an organic light emitting structure; an organic layer covering the organic light emitting structure, and filled with an inorganic material.

In one embodiment, the organic layer includes a first organic layer and a second organic layer which are stacked, and the inorganic material is disposed in one or two of the first organic layer and the second organic layer.

In one embodiment, the organic layer is provided with a groove filled with the inorganic material.

In one embodiment, the groove is formed by a plurality of connected groove units and the projection of the groove on the organic layer covers the organic layer.

In one embodiment, the organic layer includes a first organic layer and a second organic layer stacked on the first organic layer, the groove includes a first groove and a second groove, groove units of the first groove are distributed in the first organic layer, and groove units of the second groove are distributed in the second organic layer.

In one embodiment, the organic layer includes a first organic layer and a second organic layer stacked on the first organic layer, and the plurality of groove units of the groove are distributed in the first organic layer and the second organic layer.

In one embodiment, the groove units include first groove units having cross sections of semicircular ring shape, and the groove is formed by the connected first groove units.

In one embodiment, the groove units have cross sections of elongated shape, and the groove units include second groove units each parallel to the organic layer, third groove units disposed at an acute angle with respect to the organic layer, and fourth groove units disposed at an obtuse angle with respect to the organic layer, and fifth groove units disposed at right angle with respect to the organic layer, and the groove is formed by alternately connecting at least two of the second groove units, the third groove units, the fourth groove units, and the fifth groove units.

In one embodiment, the plurality of groove units are connected to form a groove having a cross section of a pulse wave shape.

In one embodiment, the pulse wave shape is a sawtooth wave shape, a rectangular wave shape, or a trapezoidal wave shape.

In one embodiment, the flexible display device further includes a reinforcing layer covering the organic layer, and the material of the reinforcing layer is an inorganic material.

In one embodiment, the organic light emitting structure includes at least one metal wiring layer including a first metal wire and a second metal wire that extend side by side, the first metal wire and the second metal wire each having concave portions and convex portions that are alternately disposed in a first direction, and the first direction is an extending direction of the first metal wire and the second metal wire.

In one embodiment, the concave portions of the first metal wire correspond to the convex portions of the second metal wire in a second direction perpendicular to the first direction, and the convex portions of the first metal wire correspond to the concave portions of the second metal wire in the second direction.

In one embodiment, the concave portions of the first metal wire and the concave portions of the second metal wire each have a flat bottom surface, and the convex portions of the first metal wire and the convex portions of the second metal wire each have a flat top surface.

In one embodiment, at least one of the convex portions of the first metal wire and the convex portions of the second metal wire has a rectangular, trapezoidal or curved cross section taken along a second direction perpendicular to the first direction.

In one embodiment, the length of the bottom surface of the concave portions of the first metal wire is equal to the length of the top surface of the convex portions of the first metal wire, and the length of the bottom surface of the concave portions of the second metal wire is equal to the length of the top surface of the convex portions of the second metal wire, and the length of the bottom surface of the concave portions of the first metal wire is equal to the length of the top surface of the convex portions of the second metal wire.

In one embodiment, the length of the bottom surface of the concave portions of the first metal wire is greater than the length of the top surface of the convex portions of the first metal wire, and the length of the bottom surface of the concave portions of the second metal wire is greater than the length of the top surface of the convex portions of the second metal wire.

In one embodiment, the concave portions of the first metal wire and the concave portions of the second metal wire are at least partially overlapped.

In one embodiment, the ratio between the length of the bottom surface of the concave portions of the first metal wire and the length of the top surface of the convex portions of the first metal wire is less than 10:1, and the ratio between the length of the bottom surface of the concave portions of the second metal wire and the length of the top surface of the convex portions of the second metal wire is less than 10:1.

In one embodiment, the length of the top surface of the convex portions of the first metal wire is greater than the length of the bottom surface of the concave portions of the first metal wire, and the length of the top surface of the convex portions of the second metal wire is greater than the length of the bottom surface the concave portions of the second metal wire.

In the flexible display device provided in the embodiments of the disclosure, the organic layer is filled with an inorganic material, so that the inorganic material is distributed in the non-planar space to form an overlapping structure with the organic layer. This design ensures the water-oxygen barrier property while reducing the maximum strain of the inorganic material during the bending deformation process, thereby reducing the risk of breakage of the inorganic material and improving the reliability of the package. In another aspect, at least one metal wiring layer in the organic light-emitting structure is provided with at least two metal wires extending side by side and having alternating concave portions and convex portions, thereby improving the bidirectional bending resistance of the metal wire, and reducing the risk of metal wire breakage when the flexible display device is bent and folded towards its front or back surface.

### BRIEF DESCRIPTION OF DRAWINGS

FIG. 1 is a schematic structural diagram of a flexible display device according to an embodiment of the present disclosure.

FIG. 2 is a schematic structural diagram of a flexible display device according to another embodiment of the present disclosure.

FIG. 3 is a schematic structural diagram of a flexible display device according to still another embodiment of the present disclosure.

FIG. 4 is a schematic structural diagram of a flexible display device according to still another embodiment of the present disclosure.

FIG. 5 is a schematic structural diagram of a flexible display device according to still another embodiment of the present disclosure.

FIG. 6 is a schematic structural diagram of a flexible display device according to still another embodiment of the present disclosure.

FIG. 7 is a schematic structural diagram of a flexible display device according to still another embodiment of the present disclosure.

FIG. 8 is a schematic structural diagram of a flexible display device according to still another embodiment of the present disclosure.

FIG. 9 is a schematic structural diagram of a flexible display device according to still another embodiment of the present disclosure.

FIG. 10 is a schematic structural diagram of a flexible display device according to still another embodiment of the present disclosure.

FIG. 11 is a flow chart showing a method of fabricating a flexible display device according to an embodiment of the disclosure.

FIG. 12 is a flow chart showing a method of fabricating a flexible display device according to another embodiment of the present disclosure.

FIG. 13 is a flow chart showing a method of fabricating a flexible display device according to still another embodiment of the present disclosure.

FIG. 14a is a cross-sectional view showing a metal wiring layer in a flexible display device according to an embodiment of the present disclosure.

FIG. 14b is a top view of a metal wiring layer in a flexible display device according to an embodiment of the disclosure.

FIG. 15a is a cross-sectional view showing a metal wiring layer in a flexible display device according to another embodiment of the present disclosure.

FIG. 15b is a top view of a metal wiring layer in a flexible display device according to another embodiment of the present disclosure.

FIG. 16a is a cross-sectional view showing a metal wiring layer in a flexible display device according to still another embodiment of the present disclosure.

FIG. 16b is a top view of a metal wiring layer in a flexible display device according to still another embodiment of the present disclosure.

FIG. 17a is a cross-sectional view showing a metal wiring layer in a flexible display device according to still another embodiment of the present disclosure.

FIG. 17b is a top view showing a metal wiring layer in a flexible display device according to still another embodiment of the present disclosure.

FIG. 18a is a cross-sectional view showing a metal wiring layer in a flexible display device according to still another embodiment of the present disclosure.

FIG. 18b is a top view showing a metal wiring layer in a flexible display device according to still another embodiment of the present disclosure.

FIG. 19a is a cross-sectional view showing a metal wiring layer in a flexible display device according to still another embodiment of the present disclosure.

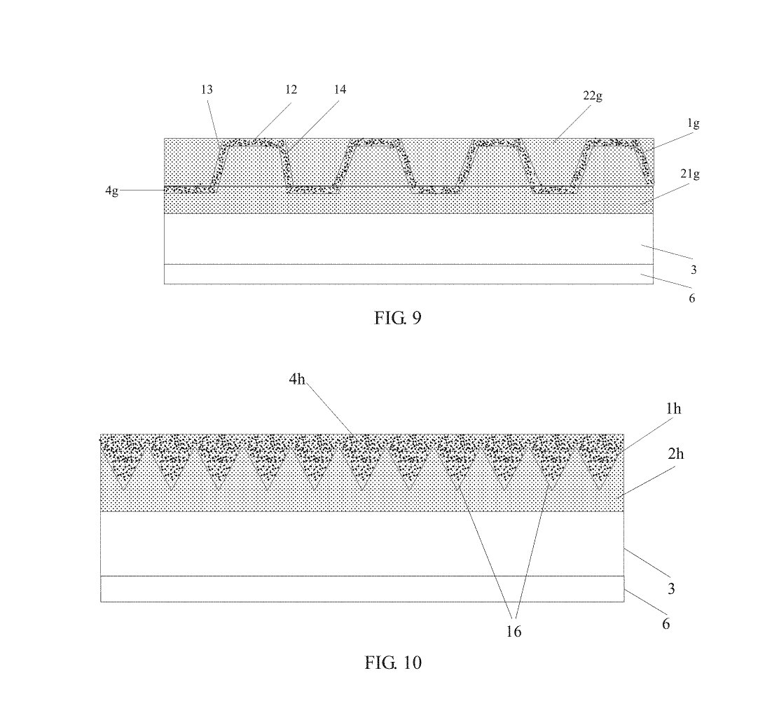

FIG. 9b is a top view of a metal wiring layer in a flexible display device according to still another embodiment of the present disclosure.

### DETAILED DESCRIPTION

In order to make the objects, technical means and advantages of the present disclosure more comprehensible, the present disclosure will be further described in detail below with reference to accompanying drawings.

Embodiments of the present disclosure provide a flexible display device including a flexible substrate, an organic light emitting structure disposed on the flexible substrate, and an organic layer covering the organic light emitting structure. The organic light emitting structure may include at least one metal wiring layer, and the organic layer is filled with an inorganic material.

By means of the filling of the inorganic material in the organic layer, the flexible display device provided by the embodiments of the disclosure allows the inorganic material to be distributed in the non-planar space to form an overlapping structure with the organic layer. This design ensures the water-oxygen barrier property, while reduces the maximum strain the inorganic material can bear during the process of bending deformation of the device to reduce the risk of breakage of the inorganic material and to improve the reliability of the package.

As to the organic layer, it may either be one layer or a plurality of stacked layers. In the case where the organic layer is a plurality of layers, the inorganic material may either be disposed in one of the layers or in a plurality of the organic layers. In one embodiment, the organic layer includes a first organic layer and a second organic layer which are stacked, and the inorganic material is disposed in one or both of the first organic layer and the second organic layer.

In one embodiment, the organic layer includes a groove, and the inorganic material is filled in the groove. Specifically, the groove may be formed by a plurality of connected groove units and its projection on the organic layer covers the organic layer. In the case where the organic layer is a plurality of layers, the groove may be designed in one of the organic layers, or may be designed in a plurality of the organic layers.

As to the plurality of groove units constituting the groove, they may either be distributed in one organic layer or in a plurality of organic layers, as long as the projection of the groove can cover the organic layer. The present disclosure is not specifically limited by this. For example, in one embodiment, the organic layer includes a first organic layer and a second organic layer which are stacked, and the plurality of groove units of the groove are distributed in the two organic layers of the first organic layer and the second organic layer. In another embodiment, the organic layer also includes two stacked organic layers, each of the organic layers including one groove, and they are a first groove and a second groove respectively. The groove units of the first groove are distributed in the first organic layer, and the groove units of the second groove are distributed in the second organic layer.

As to the shape of the groove unit, its cross section may specifically be an elongated shape or a bent elongated shape, in which the cross section is taken along a plane perpendicular to the organic layer, and the elongated shape specifically refers to a rectangle shape or a rectangle-like shape (such as a shape having two opposite long sides in zigzag form, etc.) of which the projection on the plane has a relatively large length-width ratio. As to the bent elongated shape, it may be a semicircular ring shape, a semicircular ring-like shape, a semi-elliptical ring shape, etc. The present disclosure is not specifically limited by this.

In the following, a semicircular ring shape will be taken as an example to specifically describe a groove structure formed by groove units of which the cross sections are of a bent elongated shape.

In an embodiment of the disclosure, the groove units having cross sections of a semicircular ring shape are first groove units, in which the cross section is taken along a plane perpendicular to the organic layer, and the groove is formed by the connected first groove units. As to the bending direction of the first groove units, it may be bent downward to form a semicircular ring shape with an upward opening, or may be bent upward to form a semicircular ring shape with a downward opening. The present disclosure is not limited by this.

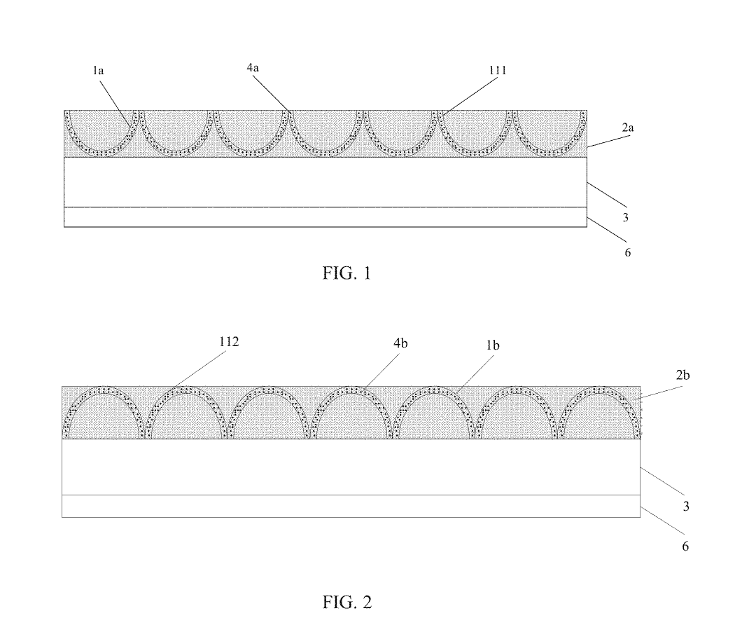

In one embodiment, as shown in FIG. 1, the flexible display device includes a flexible substrate 6, an organic light emitting structure 3 disposed on the flexible substrate 6, and an organic layer 2a covering the organic light emitting structure 3. A groove 1a is formed by the connected first groove units 111 having an upward opening. In another embodiment, as shown in FIG. 2, the groove 1b is formed by the connected first groove units 112 having a downward opening. It can be seen that, by disposing these first groove units 111 (or 112) in one organic layer 2a (or 2b) and joining them to form a groove 1a (or 1b) of which projection may cover the organic layer 2a (or 2b), the inorganic layer 4a (or 4b) covering the organic layer 2a (or 2b) may be formed by filling the groove 1a (or 1b) with an inorganic material. As to the device structure provided in this embodiment, the formation of the inorganic layer 4a (or 4b) of the curved structure only requires filling one organic layer with the inorganic material, which reduces the possibility of occurrence of fracture, improves the water-oxygen barrier property and saves material costs.

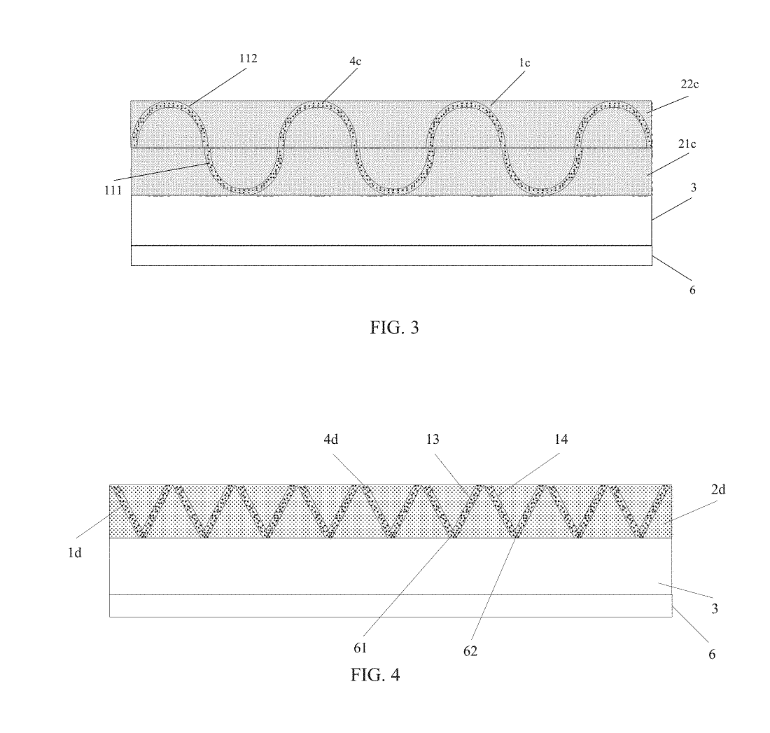

In another embodiment of the present disclosure, the groove 1c is formed by a plurality of first groove units 111 having an upward opening and a plurality of first groove units 112 having a downward opening that are alternately connected, which requires distributing these groove units in at least two organic layers. In one embodiment, as shown in FIG. 3, the number of one type of groove units which are continuously presented in the alternation of the connected two types of groove units is one, that is, a groove 1c having a shape similar to a sinusoidal wave shape is formed. Firstly, the first organic layer 21c is prepared on the organic light-emitting structure 3, and the first organic layer 21c is grooved inwardly at predetermined positions to form the plurality of first groove units 111 having an upward opening. Then, the second organic layer 22c is further prepared on the first organic layer 21c, and the second organic layer 22c is grooved inwardly at predetermined positions to form the plurality of first groove units 112 having a downward opening, which are connected to the first groove units 111 to form a continuous groove 1c of which the projection may cover the second organic layer 22c. Then, the groove 1c is filled with an inorganic material, thereby forming an inorganic layer 4c covering the organic layer.

Of course, the number of one type of groove units which is continuously presented in the alternation of the aforesaid connected two types of groove units can also be set as any number, and the width of each of the openings of the groove units may be the same or different, which is not specifically limited in the present disclosure.

In addition, the first groove units 111 (or 112) in any of the above-mentioned embodiments may be disposed in more organic layers to form grooves of more types of structures, as long as the projection of the grooves formed by the connected groove units can cover the organic layer. The distribution form of the groove units is not limited in the present disclosure.

The structure of a groove formed by groove units of which the cross sections are of elongated shape is specifically described below.

Referring to FIGS. 4 to 8, the groove units having elongated cross sections may include second groove units 12 each of which is parallel to the organic layer, third groove units 13 forming an acute angle with respect to the organic layer, fourth groove units 14 forming an obtuse angle with respect to the organic layer, and fifth groove units 15 forming a right angle with respect to the organic layer. Taking FIG. 4 as an example, the acute angle refers to an angle formed by the third groove unit 13 and the bottom surface of the organic layer 2d at the right side of the intersection point 61, and the intersection point 61 is a point at which the third groove unit 13 intersect with the bottom surface of the organic layer 2d. The obtuse angle refers to the angle formed by the fourth groove unit 14 and the bottom surface of the organic layer 2d at the right side of the intersection 62, and the intersection point 62 is the point at which the fourth groove units 14 intersect with the bottom surface of the organic layer 2d. The groove may be formed by alternately connecting at least two of the second groove units 12, the third groove units 13, the fourth groove units 14, and the fifth groove units 15 described above. For example, for a structure in which a plurality of groove units in one groove may be distributed in one organic layer, this structure may be achieved by alternately connecting the third groove units 13 and the fourth groove units 14, by alternately connecting the third groove units 13 and the fifth groove units 15, or by alternately connecting the fourth groove units 14 and the fifth groove units 15; for a structure in which the groove units of one groove needs to be distributed in a plurality of organic layers, this structure may be achieved by alternately connecting the second groove units 12 and the fifth groove units 15, by alternately connecting the third groove units 13, the second groove units 12 and the fourth groove units 14, or by alternatively connecting the third groove units 13 the second groove units 12 and the fifth groove units 15.

Taking the alternative connection of the third groove units 13 and the fourth groove units 14 as an example, the following will specifically describe the circumstances in which the groove formed by the groove units of which the cross sections are of elongated shape may be located inside one organic layer. As shown in FIG. 4, the third groove units 13 and the fourth groove units 14 alternate to form a groove 1d composed of a plurality of V-shaped structures, and the interior of the groove 1d is filled with inorganic material to form the inorganic layer 4d of which the projection covering the organic layer 2d. In this embodiment, by providing the inorganic layer with a bent structure, the water-oxygen is effectively blocked, and the release of stress is more favorable, thereby reducing the risk of breakage of the inorganic layer and ensuring the reliability of the package. This solution in which the single layer of the organic layer and the inorganic material overlap each other has a simple structure and a reduced cost.

In order to further improve the performance of the inorganic material to block water oxygen, and make the reliability of the package to be higher, more than two grooves may be provided, and then each groove is filled with an inorganic material to form a plurality of inorganic layers. Taking the embodiment shown in FIG. 4 as an example, another organic layer may be further prepared over the organic layer, and then groove units are formed in the organic layer to form a groove structure as shown in FIG. 5. Referring to FIG. 5, the flexible display device includes two organic layers disposed in a stack, in which the first organic layer 21e covers the organic light emitting structure 3, and the second organic layer 22e covers the first organic layer 21e. The two organic layers 21e and 22e are provided with grooves having the same structure, which are grooves having continuous V-shaped structure. The projection of the first groove 1e covers the first organic layer 21e, and the projection of the second groove 12e covers the second organic layers 22e. That allows the inorganic layers 41e and 42e inside the two grooves to have the same shape, while their projections may cover the respective organic layers.

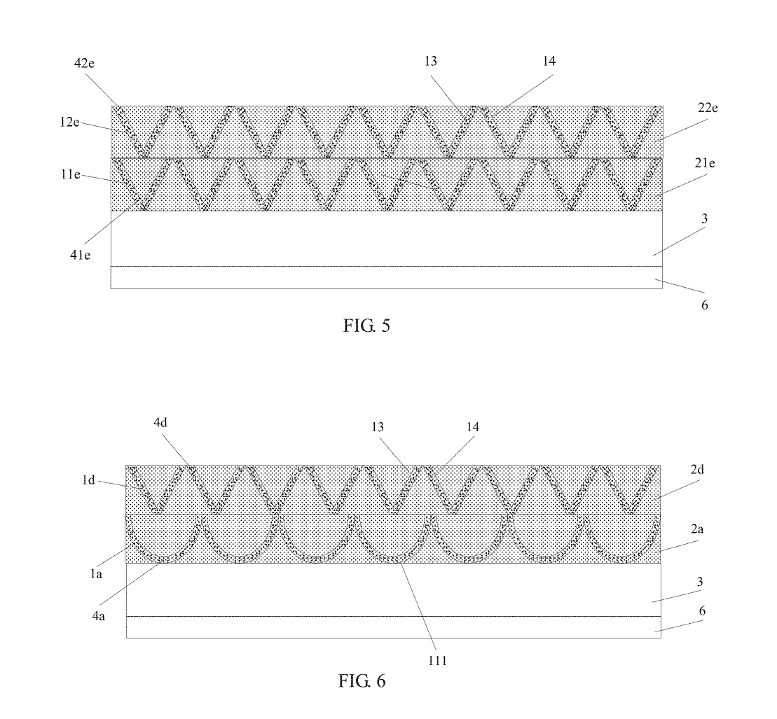

Of course, in other embodiments, the groove in the upper layer and the groove in the lower layer may be provided with different shapes. For example, the lower organic layer is grooved with a plurality of first groove units 111 with an upward opening to form a groove 1a, and the upper organic layer is grooved with the third groove units 13 and the fourth groove units 14 which are alternatively connected to form a groove 1d, so as to form a structure as shown in FIG. 6. The arrangement of multiple grooves (i.e., multiple inorganic layers) allows the device to be more resistant to water and oxygen, further reducing the likelihood of package failure and extending the life of the device.

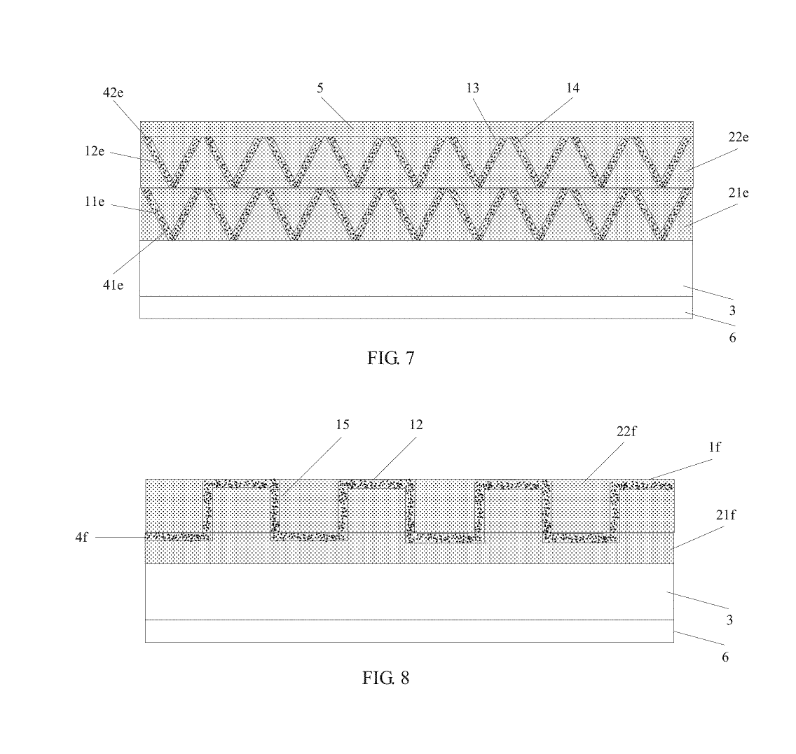

In an embodiment of the disclosure, the flexible display device further includes a reinforcing layer covering the organic layer, the reinforcing layer being composed of an inorganic material. As shown in FIG. 7, on the second organic layer 22e is disposed a reinforcing layer 5 which may cover the lower first organic layer 21e and second organic layer 22e. The reinforcing layer 5 may be composed of an inorganic material, and specifically, the material may be one or more of alumina, zirconia, silicon oxide, gallium oxide, tin oxide, silicon nitride, aluminum nitride, titanium nitride, and tantalum nitride. The reinforcing layer 5 can further ensure that the organic layer and the inorganic material underneath it will not be invaded by water and oxygen, thereby further increasing the reliability of the device package.

The following will specifically describe the circumstances where the groove units of which the cross sections are of elongated shape are required to be distributed in at least two organic layers.

In one embodiment, as shown in FIG. 8, the second groove units 12 and the fifth groove units 15 are alternately connected to form a groove 1f with rectangles with an upward opening and rectangles with a downward opening alternatively presented. The interior of the groove 1f may be filled with an inorganic material to form an inorganic layer 4f of which the projection may cover the second organic layer 22f. In this case, the fifth groove units 15 are formed in the second organic layer 22f, and the second groove units 12 need to be formed in the two organic layers of the first organic layer 21f and the second organic layer 22f.

In another embodiment, as shown in FIG. 9, the third groove units 13, the second groove units 12 and the fourth groove units 14 are alternately connected to form a groove 1g with trapezoids with an upward opening and trapezoids with a downward opening alternatively disposed. The interior of the groove 1g is filled with an inorganic material to form an inorganic layer 4g of which the projection may cover the second organic layer 22g.

As to the formation process of the inorganic layer 4g, a first organic layer 21g may firstly be prepared on the organic light emitting structure 3, and the first organic layer 21g is grooved with the second groove units 12 at predetermined positions. Then, a second organic layer 22g is successively prepared on the first organic layer 21g, and the second organic layer 22g is provided with the third groove units 13, second groove units 12 and fourth groove units 14 at predetermined positions, allowing them to be connected with the second groove units 12 in the upper of the first organic layer 21g to form the groove 1g of which the projection may cover the second organic layer 22g. Finally, the interior of the groove 1g is filled with inorganic material to form the inorganic layer 4g covering the second organic layer 22g.

Of course, the third groove units 13, the second groove units 12, and the fourth groove units 14 may be disposed in two or more organic layers to form grooves having more types of structures, as long as the projection of the groove formed by them when they are connected can cover the uppermost organic layer. The distribution form of the groove units is not limited in the present disclosure.

In an embodiment of the disclosure, the groove units are disposed at the upper portions of the organic layer, and the groove units are connected to form a groove having a pulse wave shape in cross section, the cross section being cut along a plane perpendicular to the organic layer. The pulse wave shape may be, for example, a sawtooth wave, a rectangular wave or a trapezoidal wave. That is, these groove units are formed on the upper surface of the organic layer, and are connected to form a curved structure having raised and lowered portions, thereby forming a groove of which the cross section has a pulse wave shape or a pulse wave-like shape having fluctuations.

In one embodiment, as shown in FIG. 10, the organic layer 2h is disposed on the organic light emitting structure 3, and a plurality of groove units 16 are formed in an upper portion thereof, and the plurality of groove units 16 are connected to form a sawtooth shaped groove 1h covering the organic layer 2h. The inorganic layer 4h covering the organic layer 2h may be formed by filling the groove 1g with an inorganic material. That is to say, in the present embodiment, by designing the contact faces of the organic layer and the inorganic layer to have a structure of curved surfaces that are staggered and matched, the stress accumulated in the inorganic layer is released, and the risk of fracture is reduced.

In another embodiment, in order to further promote the release of stress in the inorganic layer, the upper surface of the inorganic layer may be further provided with a structure in which a plurality of grooves or a plurality of protrusions are connected, and organic and inorganic layers may be further superposed thereon. This design may further ensure the reliability of the package.

The groove units in the above embodiments may be formed by a laser method or an etching method. For example, the first groove units 111 (or 112) and the second groove units 12 may be formed by laser sintering, and the groove units 16 may be formed by etching.

For the inorganic layer, it may be formed by chemical vapor deposition or atomic layer deposition, and the material thereof may be one or more of alumina, zirconia, silicon oxide, gallium oxide, tin oxide, silicon nitride, aluminum nitride, titanium nitride.

For the organic layer, the material may be one or more of epoxy resin, polymethyl methacrylate, polyacrylate, parylene, polyurea, polyethylene terephthalate, polyethylene naphthalate and polystyrene.

The embodiments of the present disclosure further provide a method for preparing a flexible display device. As shown in FIG. 11, the method includes:

Step 101: preparing an organic layer over an organic light emitting structure such that the organic layer covers the organic light emitting structure.

Step 102: preparing a groove in the organic layer.

Specifically, the groove may be formed by a plurality of connected groove units and the projection thereof on the organic layer covers the organic layer.

Step 103: filling the groove with an inorganic material.

In the preparation method provided by the embodiments of the present disclosure, by providing a groove in the organic layer and filling the groove with an inorganic material, the inorganic material is distributed in the non-planar space formed by the groove to form an overlapping structure with the organic layer. This design ensures the water-oxygen barrier property while facilitating the release of stress in the inorganic material during bending, thereby reducing the risk of structural fracture of the inorganic material and improving the reliability of the package.

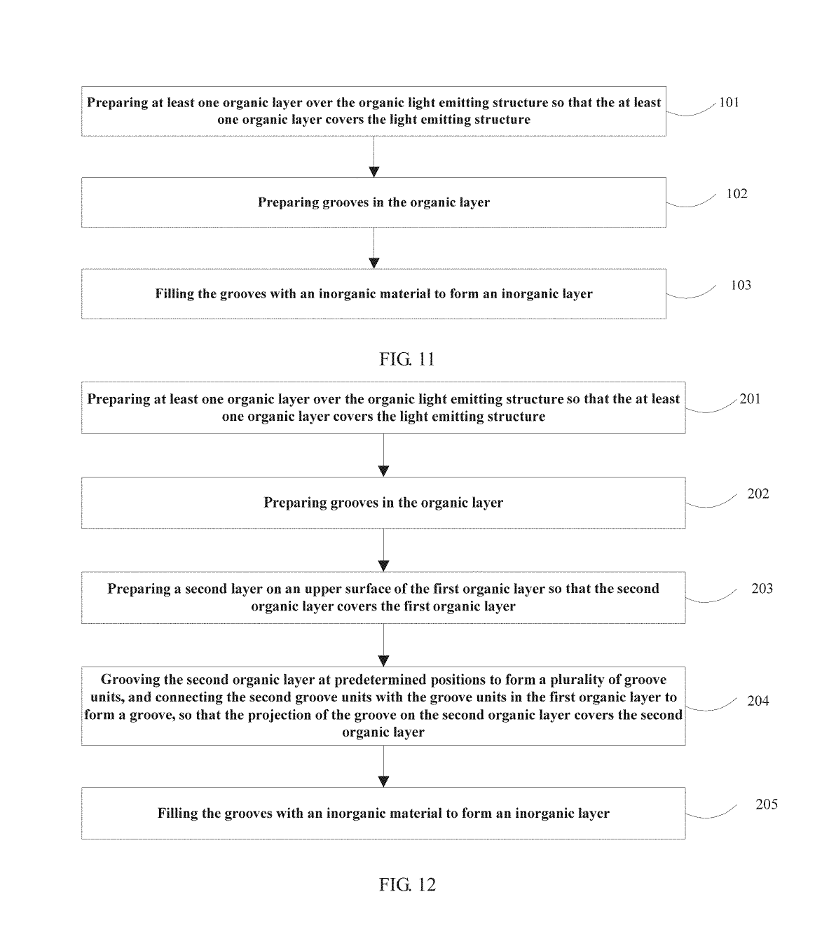

In an embodiment of the present disclosure, as shown in FIG. 12, the method specifically includes:

Step 201: preparing a first organic layer over an organic light emitting structure and making the first organic layer to cover the organic light emitting structure.

Step 202: grooving the first organic layer at predetermined positions to provide a plurality of groove units.

Step 203: preparing a second organic layer on an upper surface of the first organic layer such that the second organic layer covers the first organic layer.

Step 204: grooving the second organic layer at predetermined positions to provide a plurality of groove units, and connecting these second groove units with the groove units in the first organic layer to form a groove, so that the projection of the groove on the second organic layer covers the second organic layer.

Step 205: filling the groove with an inorganic material.

In this case, the groove units may be directionally sintered by a laser method. The inorganic material may be, for example, one or more of alumina, zirconia, silica, gallium oxide, tin oxide, silicon nitride, aluminum nitride, titanium nitride, and tantalum nitride.

For the organic layer, the material may be one or more of epoxy resin, polymethyl methacrylate, polyacrylate, parylene, polyurea, polyethylene terephthalate, polyethylene naphthalate.

The preparation method provided in this embodiment is suitable for the case where the groove needs to be formed in two organic layers, such as the structure of the groove 1g in the foregoing embodiment which is formed by the third groove units 13, the second groove units 12 and the fourth groove units 14 that are alternately connected. By using the method provided in this embodiment to design the inorganic material as being distributed in the two layers of the upper and lower organic layers, the release of stress in the brittle inorganic material is promoted, the water-oxygen barrier property is ensured, the possibility of fracture is reduced, and the life of the device is extended.

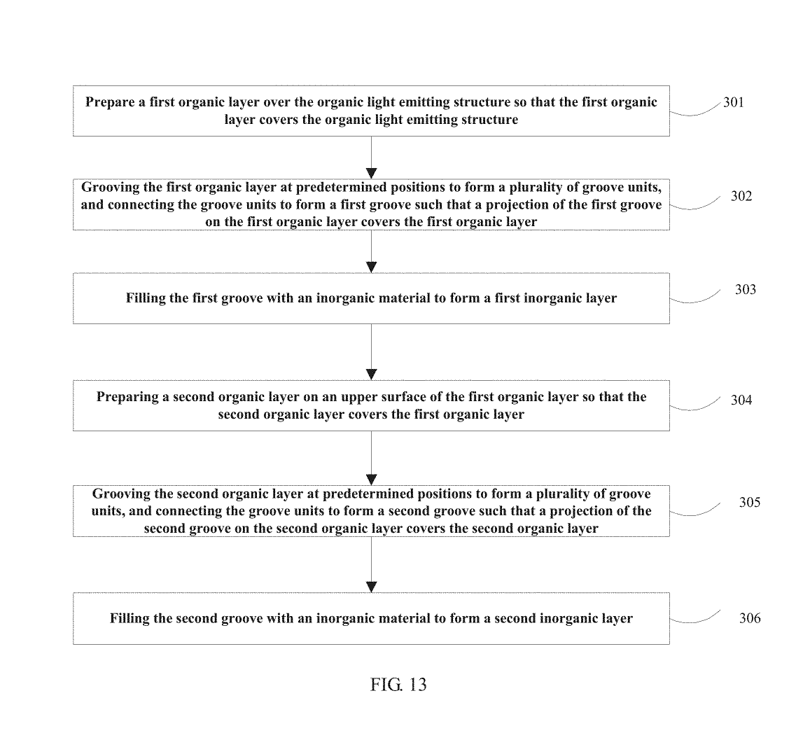

In another embodiment of the present disclosure, as shown in FIG. 13, the method specifically includes:

Step 301: preparing a first organic layer over an organic light emitting structure such that the first organic layer covers the organic light emitting structure.

Step 302: grooving the first organic layer at predetermined positions to provide a plurality of groove units, and connecting these groove units to form a first groove such that the projection thereof on the first organic layer covers the first organic layer.

Step 303: filling the first groove with an inorganic material.

Step 304: preparing a second organic layer on the upper surface of the first organic layer such that the second organic layer covers the first organic layer.

Step 305: grooving the second organic layer at predetermined positions to provide a plurality of groove units, and connecting the groove units to form a second groove such that a projection thereof on the second organic layer covers the second organic layer.

Step 306: filling the second groove with an inorganic material.

The preparation method provided in this embodiment is suitable for the case where the groove may be formed inside one organic layer, such as the structure of the groove 1d in the foregoing embodiment which is formed by the third groove units 13 and the fourth groove units 14 that are alternately connected. Meanwhile, by using the method provided in this embodiment, two inorganic material structures respectively distributed in the upper and lower organic layers may be formed, thereby further improving the water and oxygen barrier capability and enhancing the reliability of the device package.

In another aspect, the flexible display device needs to flex by a certain radius of curvature during use, and even needs to be frequently bent towards its front or back side. The stress generated, when the flexible display device is deformed, is applied to the metal wires in the metal wiring layer, posing a risk of the metal wires to be broken.

In order to provide the reliability of the flexible display device and extend its service life, it is possible to consider the design of the metal wire, such as providing holes in the metal wire, using a thinner or more flexible material for wire, or using a structure having alternate protrusions and bends to releases stress, and thus to extend the life of the wire. Although the above methods can release the stress accumulated on the metal wire to a certain extent, these methods either have a relatively high requirement on the lithographic apparatus, which increases the difficulty of the process and operation, or use materials or processing equipment that is relatively expensive. In addition, as the number of times of bending increases, the metal wires are prone to multiple micro-connections, and the resistance of the metal wires changes greatly, resulting in that the flexible display device cannot display normally.

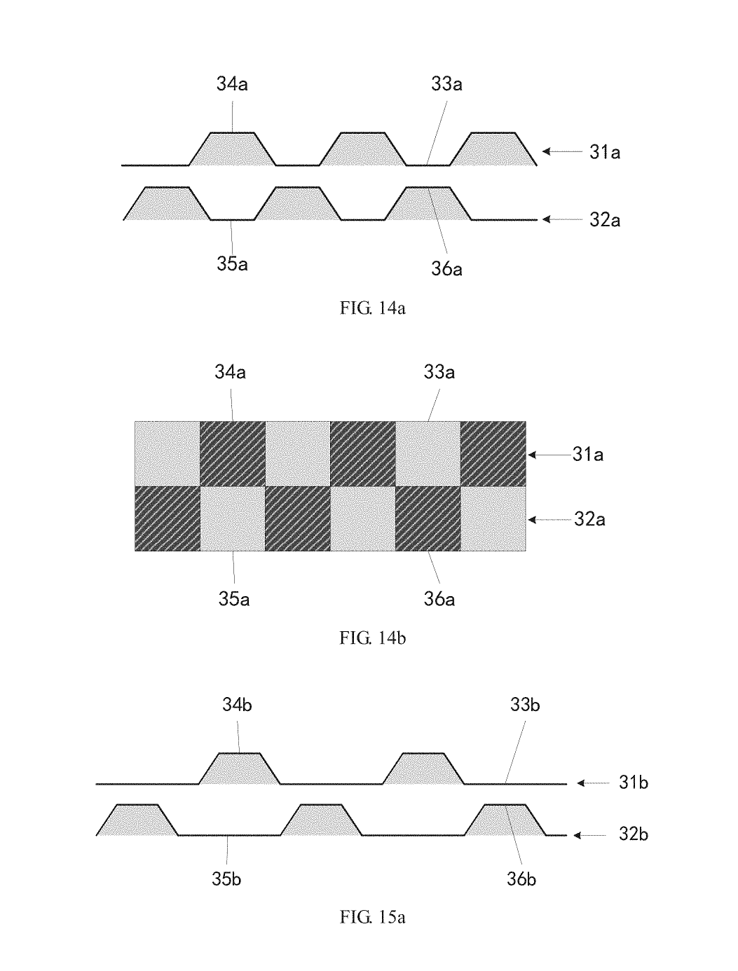

To this end, the embodiments of the present disclosure provide an improvement to at least one metal wiring layer in the flexible display device. FIG. 14a and FIG. 14b are respectively a cross-sectional view and a top view of a metal wiring layer in a flexible display device according to an embodiment of the present disclosure. As shown in FIG. 14a and FIG. 14b, the metal wiring layer includes: a first metal wire 31a and a second metal wire 32a extending side by side and having identical or similar extending directions. The first metal wire 31a has concave portions 33a and convex portions 34a which are alternately disposed in the first direction, and the second metal wire 32a has concave portions 35a and convex portions 36a which are alternately disposed in the first direction, and the first direction may be an extending direction of the first metal wire and the second metal wire. For example, the first direction may be a direction extending in the longitudinal direction of the display panel of the flexible display device.

It should be noted that the first metal wire and the second metal wire may be arranged side by side in the same layer (i.e., the first metal wire and the second metal wire in the same layer are not interlaced), or may be arranged up and down in the same layer, or it is also possible to connect the two ends of the first metal wire to the two ends of the second metal wire, respectively, which is not limited in the present disclosure. In addition, at least two metal wires are required to be disposed in the metal wiring layer of the present disclosure. Of course, the number of the metal wires may be three, four, five, etc., which is not limited in the present disclosure.

In the flexible display device provided in the embodiments of the present disclosure, at least one metal wiring layer is provided with two metal wires extending side by side and having alternate concave and convex portions, thereby improving the bidirectional bending resistance of the metal wires, and reducing the risk of metal wire breaking when flexible display devices are bent and folded towards its front or back side.

In an embodiment of the present disclosure, a concave portion 33a and a convex portion 34a of the first metal wire 31a may respectively correspond to a convex portion 36a and a concave portion 35a of the second metal wire 32a in the second direction perpendicular to the first direction. In other words, the concave portions 33a and the convex portions 34a of the first metal wire 31a are mismatched with the concave portions 35a and the convex portions 36a of the second metal wire 32a, that is, the concave portions 33a of the first metal wire 31a are arranged to correspond to the convex portions 36a of the second metal wire 32a, while the convex portions 34a of the first metal wire 31a are arranged to correspond to the concave portions 35a of the second metal wire 32a. Here, the second direction may be a direction perpendicular to the extending direction of the first metal wire and the second metal wire, for example, the second direction may be a direction in which the display panel of the flexible display device extends laterally, that is, a direction perpendicular to the display panel of the flexible display device. In the embodiment, by providing the concave portions and the convex portions of the first metal wire to be respectively corresponding to the convex portions and the concave portions of the second metal wire, the complicated situations of folding of the inwards bending and the outwards bending may be better dealt with, and therefore, resistance to bending of metal wires is increased.

In an embodiment of the disclosure, the concave portions 33a of the first metal wire 31a and the concave portions 35a of the second metal wire 32a each have a flat bottom surface, the convex portions 34a of the first metal wire 31a and the convex portions 36a of the second metal wire 32a each have a flat top surface.

Further, the convex portions 34a of the first metal wire 31a may have a rectangular or trapezoidal or arcuate cross section taken along a second direction perpendicular to the first direction. Also, the convex portions 36a of the second metal wire 32a may have a rectangular or trapezoidal or arcuate cross section in a second direction perpendicular to the first direction. It should be noted that the cross section of the convex portions 34a of the first metal wire 31a and/or the convex portions 36a of the second metal wire 32a may also have other shapes in the cross section taken along the second direction perpendicular to the first direction, such as an irregular shape, which is not limited in the present disclosure.

Further, in one embodiment, the length of the bottom surface of the concave portions 33a of the first metal wire 31a is equal to the length of the top surface of the convex portions 34a of the first metal wire 31a, and the length of the bottom surface of the concave portions 35a of the second metal wire 32a is equal to the length of the top surface of the convex portions 36a of the second metal wire 32a, and the length of the bottom surface of the concave portions 33a of the first metal wire 31a is also equal to the length of the top surface of the convex portions 36a of the second metal wire 32a. That is, the ratio between the length of the bottom surface of the concave portions 33a of the first metal wire 31a and the length of the top surface of the convex portions 34a of the first metal wire 31a is 1:1, and the ratio between the length of the bottom surface of the concave portions 35a of the second metal wire 32a and the length of the top surface of the convex portions 36a of the second metal wire 32a is 1:1, and the ratio between the length of the bottom surface of the concave portions 33a of the first metal wire 31a to the length of the top surface of the convex portions 36a of the second metal wire 32a is 1:1.

Further, the width of the convex portions 34a of the first metal wire 31a and the width of the convex portions 36a of the second metal wire 32a may be determined as desired. For example, the width of the convex portions 34a of the first metal wire 31a may be equal to the width of the convex portions 36a of the second metal wire 32a, or the width of the convex portions 34a of the first metal wire 31a may be greater than the width of the convex portions 36a of the second metal wire 32a, or the width of the convex portions 34a of the first metal wire 3a may be less than the width of the convex portions 36a of the second metal wire 32a, which is not limited in the present disclosure.

The first metal wire 31a according to the embodiment may be made of one of the materials of aluminum, titanium, and molybdenum or aluminum alloy, titanium alloy, and molybdenum alloy, and the second metal wire 32a may be made of one of the materials of aluminum, titanium, and molybdenum or aluminum alloy, titanium alloy, and molybdenum alloy. Further, the density of the first metal wire 31a and the density of the second metal wire 32a may be the same or different, which is not limited in the present disclosure.

In the flexible display device provided in the embodiments of the present disclosure, at least one metal wiring layer is formed with two metal wires extending side by side and having alternating concave portions and convex portions, and the concave portions and the convex portions of the two metal wires are provided to be offset, so as to improve the bidirectional bending resistance of the metal wire, and reduce the risk of metal breakage, when the flexible display device is bent or folded towards its front or back surfaces.

In addition, since the resistance of the metal wire does not change too much in the case where the metal wire is bent a plurality of times, the display effect and performance of the flexible display device are improved.

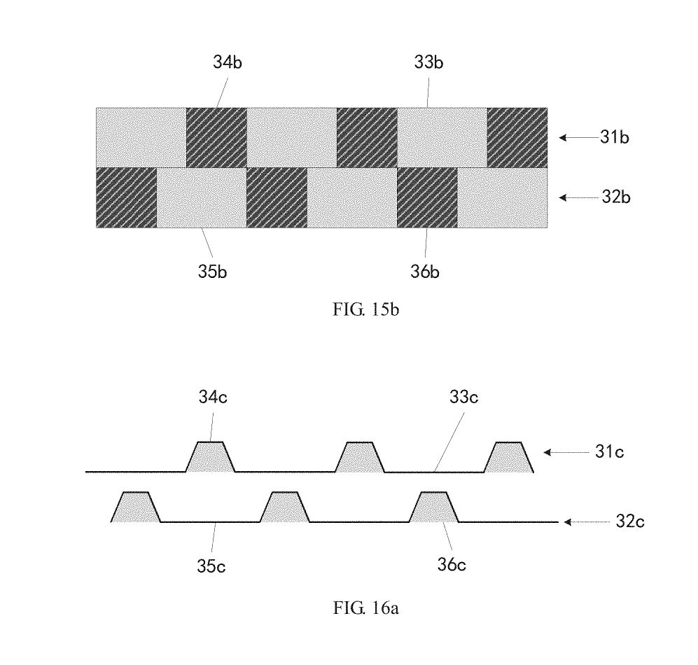

FIG. 15a and FIG. 15b are a cross-sectional view and a top view, respectively, of a metal wiring layer in a flexible display device according to another embodiment of the present disclosure. As shown in FIG. 15a and FIG. 15b, the metal wiring layer provided in the embodiment is substantially the same as that of FIG. 14a and FIG. 14b, except that the length of the bottom surface of the concave portions 33b of the first metal wire 31b of the present embodiment is greater than the length of the top surface of the convex portions 34b of the first metal wire 31b, and the length of the bottom surface of the concave portions 35b of the second metal wire 32b is greater than the length of the top surface of the convex portions 36b of the second metal wire 32b.

Specifically, the ratio between the length of the bottom surface of the concave portions 33b of the first metal wire 31b and the length of the top surface of the convex portions 34b of the first metal wire 31b may be less than 10:1, and the ratio between the length of the bottom surface of the concave portions 35b of the second metal wire 32b and the length of the top surface of the convex portions 36b of the second metal wire 32b may be less than 10:1. Preferably, the ratio between the length of the bottom surface of the concave portions 33b of the first metal wire 31b and the length of the top surface of the convex portions 34b of the first metal wire 31b is 3:2, and the ratio between the length of the bottom surface of the concave portions 35b of the second metal wire 32b and the length of the top surface of the convex portions 36b of the second metal wire 32b is 3:2.

In the flexible display device provided in the embodiments of the present disclosure, the length of the bottom surface of the concave portions of the metal wire is increased, and the length of the metal wire distributed in the longitudinal direction of the space is prolonged, thereby the bidirectional bending resistance of the metal wire is enhanced.

In one embodiment, the concave portions 33b of the first metal wire 31b and the concave portions 35b of the second metal wire 32b are at least partially overlapped, that is, a portion of the bottom surface of a concave portion 33b of the first metal wire 31b is directly connected with a portion of the bottom surface of a concave portion 35b of the second metal wire 32b. In the present embodiment, by partially overlapping the bottom surface of the concave portions of the first metal wire and the bottom surface of the concave portions of the second metal wire, the width of the bottom surface of the concave portions of the metal wire can be increased, and the metal wire will not be easily broken when the flexible display device is bi-directionally bent for multiple times. Therefore, the bending resistance of the metal wire is enhanced.

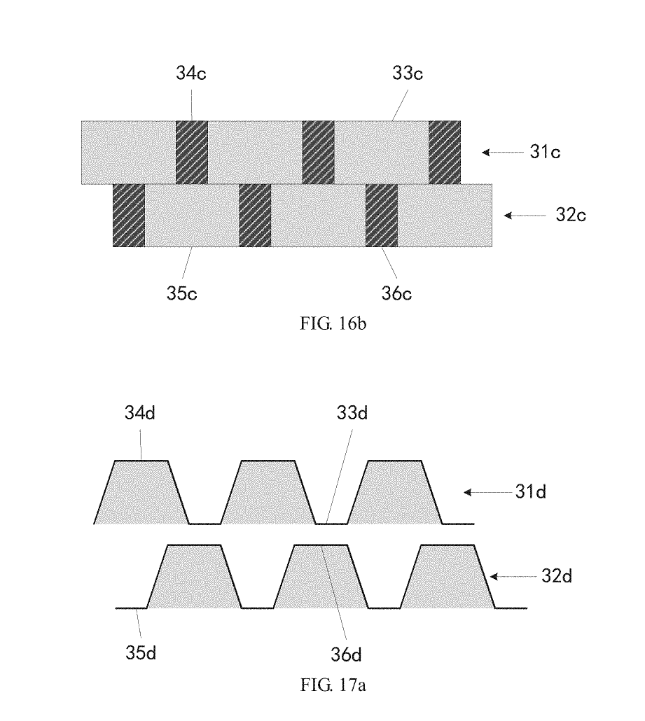

FIG. 16a and FIG. 16b are a cross-sectional view and a top view, respectively, of a metal wiring layer in a flexible display device according to still another embodiment of the present disclosure. As shown in FIG. 16a and FIG. 16b, on the basis of the metal wiring layer of the embodiment shown in FIG. 15a and FIG. 15b, the length of the bottom surface of the concave portions 33c of the first metal wire 31c of the present embodiment is longer than that of the length of the bottom surface of the concave portions 33c of the first metal wire 31c of the second embodiment.

Specifically, the ratio between the length of the bottom surface of the concave portions 33c of the first metal wire 31c and the length of the top surface of the convex portions 34c of the first metal wire 31c is 3:1, and the ratio between the length of the bottom surface of the concave portions 35c of the second metal wire 32c and the length of the top surface of the convex portions 36c of the second metal wires 32c is 3:1.

FIG. 17a and FIG. 17b are a cross-sectional view and a top view, respectively, of a metal wiring layer in a flexible display device according to still another embodiment of the present disclosure. As shown in FIG. 17a and FIG. 17b, the metal wiring layer provided in this embodiment is substantially the same as that of FIG. 14a and FIG. 14b, except that the length of the top surface of the convex portions 34d of the first metal wire 31d of the present embodiment is greater than the length of the bottom surface of the concave portions 33d of the first metal wire 31d, and the length of the top surface of the convex portions 36d of the second metal wire 32d is greater than the length of the bottom surface of the concave portions 35d of the second metal wire 32d.

Specifically, the ratio between the length of the top surface of the convex portions 34d of the first metal wire 31d and the length of the bottom surface of the concave portions 33d of the first metal wire 31d is less than 10:1, and the ratio between the top surface of the convex portions 36d of the second metal wire 32d and the length of the bottom surface of the concave portions 35d of the second metal wire 32d may be less than 10:1. Preferably, the ratio between the length of the top surface of the convex portions 34d of the first metal wire 31d and the length of the bottom surface of the concave portions 33d of the first metal wire 31d is 3:2, and the ratio between the top surface of the convex portions 36d of the second metal wire 32d and the length of the bottom surface of the concave portions 35d of the second metal wire 32d is 3:2.

In the flexible display device provided in the embodiments of the disclosure, the length of the top surface of the convex portions of the metal wire is increased, the length of the metal wire distributed in the longitudinal direction of the space is prolonged, and thus the bidirectional bending resistance of the metal wire is enhanced.

In the embodiment of the present disclosure, the first metal wire and the second metal wire may be metal wires having the same structure as described above, or may be metal wires having different structures as described below.

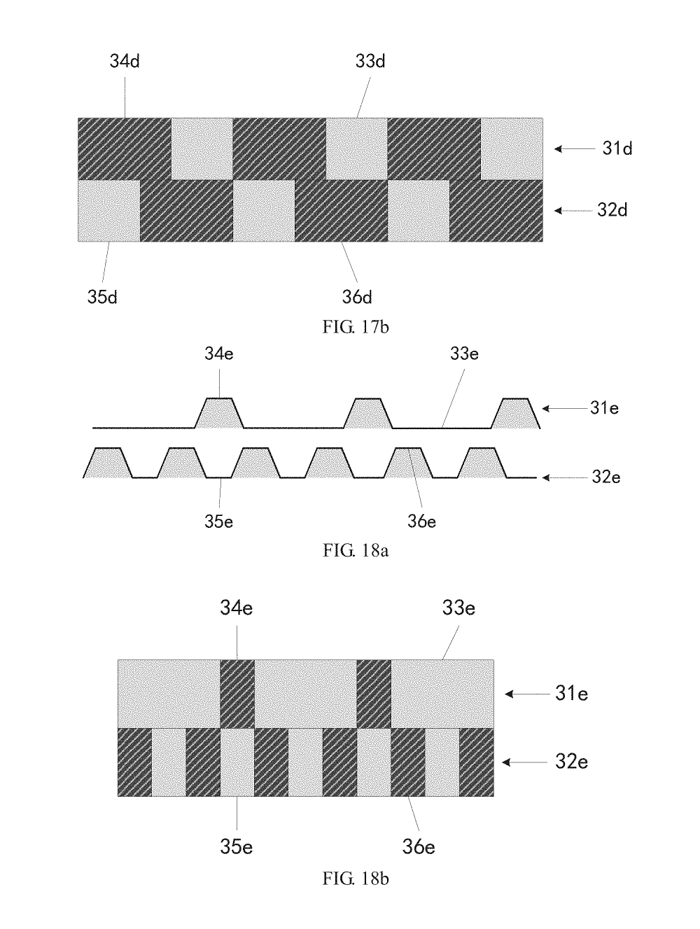

FIG. 18a and FIG. 18b are a cross-sectional view and a top view, respectively, of a metal wiring layer in a flexible display device according to an embodiment of the present disclosure. As shown in FIGS. 18a and 18b, contrary to the above embodiments, a concave portion 33e of the first metal wire 31e of the present embodiment may be provided corresponding to one concave portion 35e and two convex portions 36e of the second metal wire 32e.

Specifically, the ratio between the length of the bottom surface of the concave portions 33e of the first metal wire 31e and the length of the top surface of the convex portions 34e of the first metal wire 31e may be less than 5:1, and the ratio between the length of the bottom surface of the concave portions 35e of the second metal wire 32e and the length of the top surface of the convex portions 36e of the second metal wire 32e may be less than 3:2. Preferably, the ratio between the length of the bottom surface of the concave portions 33e of the first metal wire 31e and the length of the bottom surface of the concave portions 35e of the second metal wire 32e is 3:1, and the ratio between the length of the top surface of the convex portions 34e of the first metal wire 31e and the length of the top surface of the convex portions 36e of the second metal wire 32e is 1:1.

In the flexible display device provided in the embodiments of the present disclosure the length of the bottom surface of the concave portions of the first metal wire and the length of the top surface of the convex portions of the second metal wire are increased, respectively, and the lengths of distribution of the first metal wire and the second metal wire in the longitudinal direction of the space is prolonged. Therefore, the bidirectional bending resistance of the wire is enhanced.

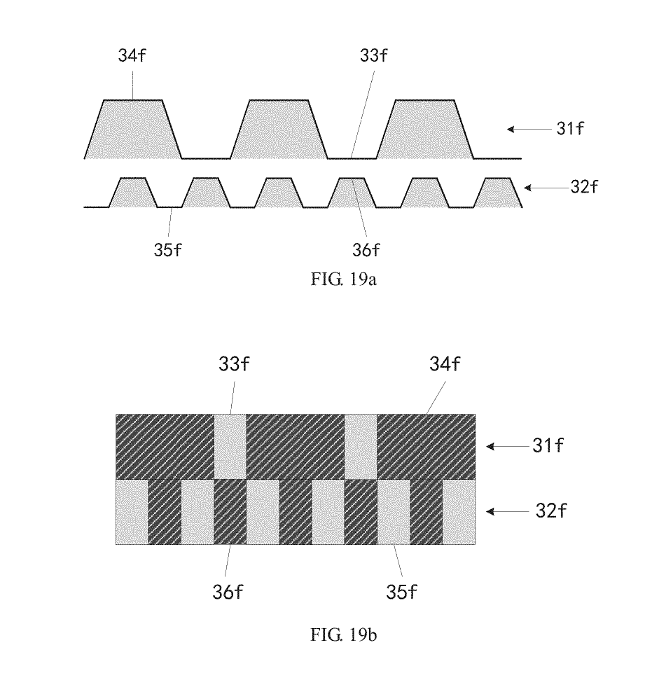

FIG. 19a and FIG. 19b are a cross-sectional view and a top view, respectively, of a metal wiring layer in a flexible display device according to another embodiment of the present disclosure. As shown in FIG. 19a and FIG. 19b, contrary to the embodiment shown in FIG. 18a and FIG. 18b, a convex portion 34f of the first metal wire 31f of the present embodiment may be disposed corresponding to two concave portions 35f and one convex portion 36f of the second metal wire 32f.

Specifically, the ratio between the length of the top surface of the convex portions 34f of the first metal wire 31f and the length of the bottom surface of the concave portions 33f of the first metal wire 31f is less than 5:1, and the ratio between the top surface of the convex portions 36f of the second metal wire 32f and the length of the bottom surface of the concave portions 35f of the second metal wire 32f may be less than 3:2. Preferably, the ratio between the length of the top surface of the convex portions 34f of the first metal wire 31f and the length of the top surface of the convex portions 36f of the second metal wire 32f is 3:1, and the ratio between the bottom surface of the concave portions 33f of the first metal wire 31f the length and the length of the bottom surface of the concave portions 35f of the second metal wire 32f is 1:1.

In the flexible display device provided in the embodiments of the disclosure, the length of the top surface of the convex portions of the first metal wire and the length of the bottom surface of the concave portions of the second metal wire are increased, respectively, and the lengths of distribution of the first metal wire and the second metal wire in the longitudinal direction of the space are extended. Therefore, the bidirectional bending resistance of the wires is enhanced.

In the flexible display device provided in the embodiments of the disclosure, by filling the organic layer with the inorganic material, the inorganic material is distributed in the non-planar space to form an overlapping structure with the organic layer. This design ensures the water-oxygen barrier property while reducing the maximum strain of the inorganic material during the bending deformation process, thereby reducing the risk of breakage of the inorganic material and improving the reliability of the package. In another aspect, at least one metal wiring layer in the organic light-emitting structure is provided with two metal wires extending side by side and having concave portions and convex portions arranged alternately, thereby enhancing the bidirectional bending resistance of the metal wires, so that the risk of wire breakage is reduced when the flexible display device is folded towards the front or back side.

The above are only the preferred embodiments of the present disclosure, and are not intended to limit the present invention. Any modifications, equivalents, and substitutions etc. within the spirit and scope of the present disclosure are intended to be included in the scope of protection of the present invention.

What is claimed is:

1. A flexible display device, comprising:
an organic light emitting structure; and
an organic layer covering the organic light emitting structure, and filled with an inorganic material.

2. The flexible display device according to claim 1, wherein the organic layer has one or more layers, and the inorganic material is disposed in at least one of the one or more layers of the organic layer.

3. The flexible display device according to claim 2, wherein the organic layer comprises a first organic layer and a second organic layer which are stacked, the inorganic material is disposed in one or both of the first organic layer and the second organic layer.

4. The flexible display device according to claim 2, wherein the organic layer disposed with the inorganic material is provided with a groove filled with the inorganic material.

5. The flexible display device according to claim 4, wherein the groove is formed by a plurality of connected groove units, and a projection of the groove on the organic layer covers the organic layer.

6. The flexible display device according to claim 5, wherein the organic layer comprises a first organic layer and a second organic layer stacked on the first organic layer, the groove comprises a first groove and a second groove, groove units of the first groove are distributed in the first organic layer, and groove units of the second groove are distributed in the second organic layer.

7. The flexible display device according to claim 5, wherein the organic layer comprises a first organic layer and a second organic layer stacked on the first organic layer, and the plurality of groove units of the groove are distributed in the first organic layer and the second organic layer.

8. The flexible display device according to claim 5, wherein the groove units comprise first groove units having cross sections of semicircular ring shape, and the groove is formed by the connected first groove units.

9. The flexible display device according to claim 5, wherein cross sections of the groove units are of elongated shape, and the groove units comprise second groove units each parallel to the organic layer, third groove units disposed at an acute angle with respect to the organic layer, fourth groove units disposed at an obtuse angle with respect to the organic layer, and fifth groove units disposed at right angle with respect to the organic layer, the groove being formed by alternately connecting at least two of the second groove units, the third groove units, the fourth groove units and the fifth groove units.

10. The flexible display device according to claim 5, wherein the plurality of groove units are connected to form a groove having a pulse wave shape in cross section.

11. The flexible display device according to claim 10, wherein the pulse wave shape is a sawtooth wave shape, a rectangular wave shape or a trapezoidal wave shape, and the flexible display device further comprises a reinforcing layer covering the organic layer, a material of the reinforcing layer being an inorganic material.

12. A flexible display device, comprising at least one metal wiring layer, the metal wiring layer comprising at least two metal wires extending side by side, the at least two metal wires having concave portions and convex portions alternately disposed in a first direction.

13. The flexible display device according to claim 12, wherein the metal wiring layer comprises two metal wires of a first metal wire and a second metal wire.

14. The flexible display according to claim 13, wherein the first direction is an extending direction of the first metal wire and the second metal wire.

15. The flexible display device according to claim 13, wherein the concave portions of the first metal wire correspond to the convex portions of the second metal wire in a second direction perpendicular to the first direction, and the convex portions of the first metal wire correspond to the concave portions of the second metal wire in the second direction.

16. The flexible display device according to claim 13, wherein the concave portions of the first metal wire and the concave portions of the second metal wire each has a flat bottom surface, and the convex portions of the first metal wire and the convex portions of the second metal wires each has a flat top surface.

17. The flexible display device according to claim 13, wherein at least one of the convex portions of the first metal wire and the convex portions of the second metal wire has a rectangular or trapezoidal or curved cross section taken along a second direction perpendicular to the first direction.

18. The flexible display device according to claim 13, wherein a length of the bottom surface of the concave portions of the first metal wire is greater than or equal to a length of the top surface of the convex portions of the first metal wire, and a length of a bottom surface of the concave portions of the second metal wire is greater than or equal to a length of the top surface of the convex portions of the second metal wire, and a length of the bottom surface of the concave portions of the first metal wire is equal to length of the top surface of the convex portions of the second metal wire.

19. The flexible display device according to claim 13, wherein the concave portions of the first metal wire and the concave portions of the second metal wire are at least partially overlapped.

20. A method of preparing a flexible display device, comprising:
providing an organic light emitting structure;
preparing an organic layer over the organic light emitting structure so that the organic layer covers the organic light emitting structure;
preparing a groove in the organic layer; and
filling the groove with an inorganic material.
